(19) United States
(12) Patent Application Publication
(10) Pub. No.: US 2023/0091271 A1
(43) Pub. Date: Mar. 23, 2023

(54) DISPLAY DEVICE

(71) Applicant: SHARP KABUSHIKI KAISHA, Sakai City, Osaka (JP)

(72) Inventors: Akira OHSHIMA, Sakai City, Osaka (JP); SHIGERU AOMORI, Sakai City, Osaka (JP); JUN SAKUMA, Sakai City, Osaka (JP); YASUSHI ASAOKA, Sakai City, Osaka (JP)

(21) Appl. No.: 17/798,828

(22) PCT Filed: Mar. 2, 2020
(86) PCT No.: PCT/JP2020/008759

§ 371 Date: Aug. 10, 2022

(51) Int. Cl. H01L 51/52

(52) U.S. Cl. CPC H01L 51/5284; H01L 27/3244

(57) ABSTRACT

A display device includes a substrate and a light-emitting element provided on the substrate. The light-emitting element includes a light-emitting portion and a first light-exiting portion. The light-emitting portion includes, in order from the substrate side, a first electrode, a light-emitting layer, a second electrode, and a light absorption layer. The first light-exiting portion includes a first light-reflecting layer provided at an incline on the substrate, and a first opening provided in the light absorption layer.

### TECHNICAL FIELD

The present invention relates to a display device.

### BACKGROUND ART

In recent years, a self-luminous display device using a light-emitting element (electroluminescence (hereinafter referred to as “EL”) element) employing an EL phenomenon has been developed as a display device instead of a liquid crystal display device.

The EL element has a configuration in which a light-emitting layer containing a light-emitting material is interposed between two electrodes. Subpixels including red color (R) EL elements, subpixels including green color (G) EL elements, and subpixels including blue color (B) EL elements arrayed on a substrate are selectively made to emit light with desired luminance by use of thin-film transistors (TFTs) to display intended images. Between every set of mutually-adjacent EL elements, a bank (partition) is disposed to define light-emitting regions of the subpixels. The light-emitting layer in each EL element is formed in an opening in the bank by use of a vapor deposition mask. Light generated in the light-emitting layer is extracted outside the display device from the opening of the bank.

In a display device described in PTL 1, a base having a forwardly tapered shape is formed on a substrate, with electrodes and a light-emitting layer provided on an inclined face of the base. The light generated by the light-emitting layers is extracted from an opening provided above the base.

### CITATION LIST

### Patent Literature

PTL 1: JP 2015-109190 A (published on Jun. 11, 2015)

### SUMMARY OF INVENTION

### Technical Problem

In a self-luminous display device, a portion of light generated by the light-emitting layer is totally reflected at an interface between layers having different refractive indices, and propagates, attenuates, and disappears in a lateral direction (direction parallel to the electrodes) along the interface. Therefore, there is a problem in that, of the light generated by the light-emitting layer, about 20% is extracted outside the display device with most of the light not being extracted outside the display device.

To address this problem, an area of the light-emitting layer and an opening area of the opening of the bank can be enlarged to extract a sufficient amount of light.

Nevertheless, enlarging the opening area of the opening of the bank increases the effect of external light reflection. As a result, it is necessary to provide an anti-reflective film that prevents reflection of external light to ensure viewability. Such an anti-reflective film inhibits the transmission of light from the light-emitting layer, and thus there is a problem in that light transmission loss occurs, further deteriorating the light extraction efficiency.

Further, in the display device described in PTL 1, the electrodes and the light-emitting layers are provided on an inclined face of the base, and thus a film thickness tends to be non-uniform, causing variation in properties such as luminous efficiency. In addition, in this display device, due to the significant effect of external light reflection, it is necessary to provide an anti-reflective film which can reduce the light extraction efficiency.

An aspect of the present invention has been made in view of the above-mentioned problems, and an object thereof is to provide a display device having a high light extraction efficiency and configured to suppress external light reflection.

### Solution to Problem

The display device according to an aspect of the present invention is a display device including a substrate, and a light-emitting element provided on the substrate. The light-emitting element includes a light-emitting portion, and a first light-exiting portion adjacent to the light-emitting portion. The light-emitting portion includes, in order from the substrate side, a first electrode, a light-emitting layer, a second electrode, and a light absorption layer. The first light-exiting portion includes a first light-reflecting layer provided at an incline on the substrate, and a first opening provided in the light absorption layer.

In the display device according to an aspect of the present invention, at least one second light-reflecting layer is provided between the substrate and the first electrode, between the first electrode and the light-emitting layer, between the light-emitting layer and the second electrode, and between the second electrode and the light absorption layer, and a portion of light generated by the light-emitting layer is reflected by the at least one second light-reflecting layer and guided to the first light-exiting portion.

In the display device according to an aspect of the present invention, the at least one second light-reflecting layer has a refractive index lower than that of the light-emitting layer.

In the display device according to an aspect of the present invention, the second light-reflecting layer is constituted by a plurality of layers, the plurality of layers have a refractive index that decreases in order from a layer closest to the light-emitting layer to a layer farthest from the light-emitting layer, and the layer closest to the light-emitting layer has a refractive index lower than that of the light-emitting layer.

In the display device according to an aspect of the present invention, the at least one second light-reflecting layer includes a metal layer formed of a metal material.

In the display device according to an aspect of the present invention, the at least one second light-reflecting layer includes a gas layer formed of a gas.

In the display device according to an aspect of the present invention, the at least one second light-reflecting layer has unevenness on a surface opposing the light-emitting layer.

In the display device according to an aspect of the present invention, the light absorption layer has unevenness on a surface on a side opposite to the light-emitting layer.

In the display device according to an aspect of the present invention, the first opening has unevenness on an opening face.

The display device according to an aspect of the present invention further includes a light-scattering layer provided on a surface of the light absorption layer on a side opposite to the light-emitting layer and configured to scatter light.

In the display device according to an aspect of the present invention, side surfaces of the light-emitting layer include a contact surface in contact with the first light-exiting portion, an opposing side surface opposing the contact surface, and an intersecting side surface that intersects the contact surface, an insulating transparent layer and a third light-reflecting layer are provided in this order on the opposing side surface and the intersecting side surface, and a reflective surface of the third light-reflecting layer on the intersecting side surface intersects the first light-exiting portion at an intersection angle less than 90° in a plan view.

In the display device according to an aspect of the present invention, the first light-exiting portion surrounds the light-emitting layer.

In the display device according to an aspect of the present invention, the first opening does not overlap the light-emitting layer.

The display device according to an aspect of the present invention further includes a second light-exiting portion including a second opening provided in the light absorption layer, the second opening overlapping the light-emitting layer.

### Advantageous Effects of Invention

According to an aspect of the present invention, it is possible to provide a display device having a high light extraction efficiency and configured to suppress external light reflection.

### BRIEF DESCRIPTION OF DRAWINGS

FIG. 1 schematically illustrates an example of a configuration of a display device according to a first embodiment of the present invention, (a) being a plan view as viewed from a viewing side, (b) being a cross-sectional view taken along line A-A in (a), (c) being a cross-sectional view describing movement of light generated in a light-emitting layer, (d) being a cross-sectional taken along line A′-A′ in (c), and (e) being an enlarged cross-sectional view illustrating movement of light in a light-emitting portion.

FIG. 2(a) is a cross-sectional view schematically illustrating an example of a configuration of a display device according to a second embodiment of the present invention, and (b) is a cross-sectional view describing the movement of the light generated in the light-emitting layer.

FIG. 3 describes the movement of the light in the light-emitting portion of the display device according to the second embodiment of the present invention, (a) being an enlarged cross-sectional view of a case in which a second light-reflecting layer is a single layer, and (b) being an enlarged cross-sectional view in a case in which the second light-reflecting layer is multi-layered.

FIG. 4 schematically illustrates an example of a configuration of a display device according to a third embodiment of the present invention, (a) being a plan view as viewed from a viewing side, and (b) being a cross-sectional view taken along line B-B in (a).

FIG. 5 schematically illustrating an example of a configuration of a display device according to a fourth embodiment of the present invention (a) being a plan view as viewed from a viewing side, and (b) being a cross-sectional view taken along line C-C in (a).

FIG. 6 is a cross-sectional view schematically illustrating an example of a configuration of a display device according to a fifth embodiment of the present invention.

FIG. 7 is a cross-sectional view schematically illustrating an example of a configuration of a display device according to a sixth embodiment of the present invention.

FIG. 8 is a cross-sectional view schematically illustrating an example of a configuration of a display device according to a seventh embodiment of the present invention.

FIG. 9 is a cross-sectional view schematically illustrating an example of a configuration of a display device according to an eighth embodiment of the present invention.

FIG. 10 is a diagram illustrating a manufacturing method of a display device according to a ninth embodiment of the present invention.

FIG. 11 is a diagram illustrating a manufacturing method of a display device according to a tenth embodiment of the present invention.

FIG. 12 is a diagram illustrating a manufacturing method of a display device according to an eleventh embodiment of the present invention.

### DESCRIPTION OF EMBODIMENTS

Hereinafter, a “lower layer” refers to a layer formed in a process before the layer being compared, and an “upper layer” refers to a layer formed in a process after the layer being compared.

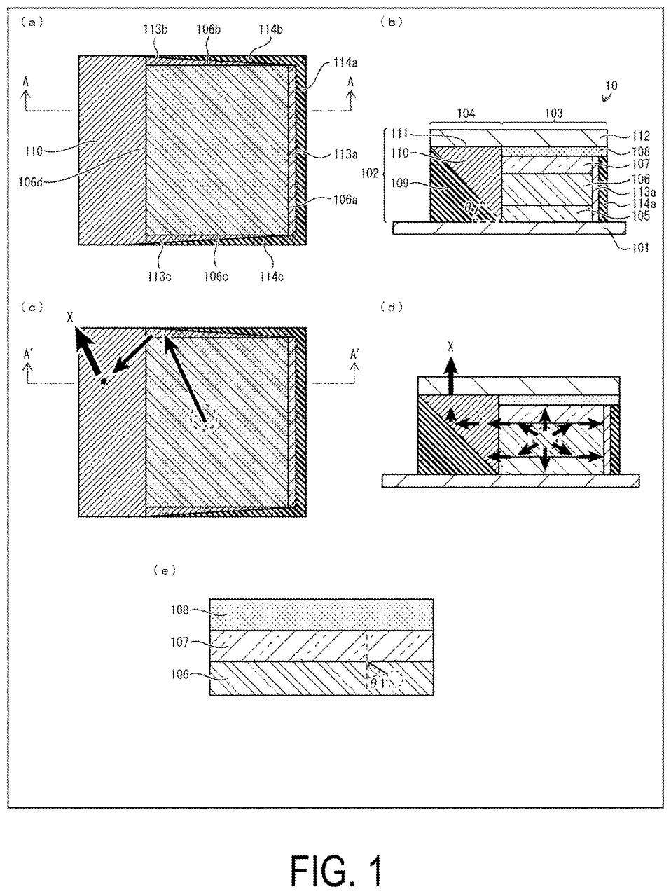

Embodiments of the disclosure will be described with reference to FIG. 1 to FIG. 12 as follows. Hereinafter, for convenience of explanation, components having the same functions as those described in a specific embodiment are appended with the same reference signs, and descriptions thereof may be omitted.

### First Embodiment

A first embodiment of the present invention will now be described with reference to FIG. 1.

FIG. 1 schematically illustrates an example of a configuration of a display device according to the present embodiment, (a) being a plan view as viewed from a viewing side, (b) being a cross-sectional view taken along line A-A in (a), (c) being a cross-sectional view describing movement of light generated in a light-emitting layer, (d) being a cross-sectional taken along line A′-A′ in (c), and (e) being an enlarged cross-sectional view illustrating movement of light in a light-emitting portion. In (e) of FIG. 1, a configuration of lower layers below the light-emitting layer is omitted.

As illustrated in (b) of FIG. 1, a display device 10 according to the present embodiment is a display device including a substrate 101 and a light-emitting element 102 provided on the substrate 101. The light-emitting element 102 includes a light-emitting portion 103 and a first light-exiting portion 104 adjacent to the light-emitting portion 103. The light-emitting portion 103 includes, in order from the substrate 101 side, a first electrode 105, a light-emitting layer 106, a second electrode 107, and a light absorption layer 108. The first light-exiting portion 104 includes a first light-reflecting layer 109 provided at an incline at an inclination angle θ on the substrate 101, and a first opening 111 provided on the light absorption layer 108.

Further, as illustrated in (a) and (b) of FIG. 1, in the display device 10, the first light-exiting portion 104 is provided adjacent to one of four sides of the light-emitting layer 106 having a quadrangular shape, and is provided with a waveguide 110 configured to guide light reflected by the first light-reflecting layer 109 to the first opening 111.

Further, insulating transparent layers 113a, 113b, 113c and third light-reflecting layers 114a, 114b, 114c surround the remaining three sides of the light-emitting layer 106. That is, side surfaces of the light-emitting layer 106 include a contact surface 106d in contact with the first light-exiting portion 104, an opposing side surface 106a opposing the contact surface 106d, and intersecting side surfaces 106b, 106c that intersect the contact surface 106d. The insulating transparent layers 113a, 113b, 113c and the third light-reflecting layers 114a, 114b, 114c are provided in this order on the opposing side surface 106a and the intersecting side surfaces 106b, 106c.

The third light-reflecting layers 114a, 114b, 114c are provided in a lateral U-shape as a whole, and reflective surfaces of the third light-reflecting layers 114b, 114c provided on the intersecting side surfaces 106b, 106c intersect the first light-exiting portion 104 at an intersection angle less than 90°, in a plan view. Note that a lower limit value of the intersection angle between the reflective surfaces of the third light-reflecting layers 114b, 114c with the first light-exiting portion 104 can be adjusted as appropriate in accordance with a size and the like of the light-emitting layer 106, and can be, for example, 45° or greater.

Further, the reflective surfaces of the third light-reflecting layers 114b, 114c may each be constituted by one flat face or a combination of a plurality of flat faces, or may be constituted by one curved face or a combination of a plurality of curved faces, or may be constituted by a combination of one or a plurality of flat faces and one or a plurality of curved faces.

Note that the intersection angle between the reflective surface of the third light-reflecting layer 114b or 114c and the first light-exiting portion 104 refers to an angle at which a line segment connecting both end portions of the reflective surface of the third light-reflecting layer 114b or 114c intersects the first light-exiting portion 104, in a plan view.

The insulating transparent layers 113b, 113c provided on the intersecting side surfaces 106b, 106c communicate with the waveguide 110 of the first light-exiting portion 104.

Here, the waveguide 110 and the insulating transparent layers 113a, 113b, 113c are made of any material having transparency and insulating properties such as, for example, plastic, to prevent shorting between electrodes.

The first light-reflecting layer 109 and the third light-reflecting layers 114a, 114b, 114c are made of a material having high reflectivity, such as a metal such as silver or aluminum, for example.

A light absorption layer 108 absorbs external light, and thus can prevent external light reflection. Accordingly, the display device 10 can ensure good viewability even without an anti-reflective film (linear polarizer, 1/λ plate, or the like), which causes light transmission loss, being provided.

In the display device 10, the light-emitting portion 103 including the light-emitting layer 106 and the light absorption layer 108 is responsible for light emission, and emits light to outside of the display device 10. On the other hand, the light-exiting portion 104 provided with the first opening 111 is responsible for emitting light generated by the light-emitting layer 106 by utilizing reflection. Then, external light is absorbed by the light absorption layer 108. With these configurations, the effect of external light reflection is small and the light transmission loss is low, making it possible to efficiently extract light generated in the light-emitting layer.

The display device 10 according to the present embodiment will be described in more detail below.

### Substrate 101

The substrate 101 is not particularly limited, and a known support substrate including, for example, an insulating substrate, a barrier layer, or a thin film transistor (TFT) can be used, for example.

The insulating substrate is not particularly limited as long as it has insulating properties. The insulating substrate used may be one of a variety of known insulating substrates, such as transparent substrates such as inorganic material substrates including a glass substrate and a quartz substrate, for example; plastic substrates such as substrates made from polyethylene terephthalate or polyimide resin, for example; and non-transparent substrates such as semiconductor substrates including silicon wafers, substrates obtained by coating an insulating material on a surface of a metal substrate, and substrates obtained by insulation-treating a surface of a metal substrate, for example.

The barrier layer is a layer that inhibits foreign matters such as water and oxygen from entering the TFT layer, and can be formed by a silicon oxide film, a silicon nitride film, or a silicon oxynitride film, or by a layered film of these, formed by chemical vapor deposition (CVD), for example.

The TFT layer includes a semiconductor film, an inorganic insulating film (gate insulating film) in an upper layer overlying the semiconductor film, a gate electrode and a gate wiring line in an upper layer overlying the inorganic insulating film, an inorganic insulating film in an upper layer overlying the gate electrode and the gate wiring line, a capacitance electrode in an upper layer overlying the inorganic insulating film, an inorganic insulating film in an upper layer overlying the capacitance electrode, a source wiring line in an upper layer overlying the inorganic insulating film, and a flattening film (interlayer insulating film) in an upper layer overlying the source wiring line.

The semiconductor film is constituted of, for example, a low-temperature polysilicon (LTPS) or an oxide semiconductor (for example, an In—Ga—Zn—O-based semiconductor), and a transistor (TFT) is configured to include the semiconductor film and the gate electrode. The transistor may have a top gate structure or may have a bottom gate structure.

The gate electrode, the gate wiring line, the capacitance electrode, and the source wiring line are each composed of a single layer film or a layered film of a metal including at least one of aluminum, tungsten, molybdenum, tantalum, chromium, titanium, and copper, for example.

The inorganic insulating film can be formed of, for example, a silicon oxide (SiOx) film or a silicon nitride (SiNx) film, or a layered film of these, formed by CVD. The flattening film may be formed of coatable organic materials such as polyimide and acrylic, for example.

### Light-Emitting Element 102

The light-emitting element 102 includes the light-emitting portion 103 and the first light-exiting portion 104 and, as necessary, a transparent substrate 112 is layered thereon, covering these.

The transparent substrate 112, as a protection layer, prevents oxygen and moisture from entering the light-emitting element 102 from the outside. Note that the transparent substrate 112 is provided common to all subpixels.

The light-emitting element 102 may be an organic light-emitting diode (OLED), or may be an inorganic light-emitting diode, or may be a quantum dot light-emitting diode (QLED). Further, the light-emitting element 102 may be a micro light-emitting diode (LED). The light-emitting element 102 is formed for each subpixel, and a subpixel circuit that controls the light-emitting element 102 is formed in the TFT layer of the substrate 101.

### Light-Emitting Portion 103

The light-emitting portion 103 refers to a region of the light-emitting element 102 covered by the light absorption layer 108 in a plan view, and includes, in order from the substrate 101 side, the first electrode 105, the light-emitting layer 106, the second electrode 107, and the light absorption layer 108.

The light-emitting portion 103 may further include, as necessary, the insulating transparent layers 113a, 113b, 113c, and the third light-reflecting layers 114a, 114b, 114c.

### First Light-Exiting Portion 104

The first light-exiting portion 104 refers to a region of the light-emitting element 102 that overlaps the first opening 111 in a plan view and is not covered by the light absorption layer 108, and includes the first light-reflecting layer 109 provided at an incline on the substrate 101, and the first opening 111 provided in the light absorption layer 108.

The first light-exiting portion 104 may further include the waveguide 110 provided so as to further guide the light reflected by the first light-reflecting layer 109 to the first opening 111, as necessary.

### First Electrode 105 and Second Electrode 107

The first electrode 105, which is a lower layer electrode, is formed for each subpixel, and is connected to the corresponding TFT via a contact hole provided in a lower layer.

The second electrode 107, which is an upper layer electrode, is formed for each subpixel, and is connected to a wiring line or the like via a contact hole provided in an upper layer. However, in a case of a shape that provides an opening for extraction in a portion of one side or the like, the second electrode 107 may be a common electrode commonly provided to the subpixels.

The first electrode 105 and the second electrode 107 may be transparent electrodes that use a transparent electrode material, or may be reflective electrodes that use a reflective electrode material or electrodes including a reflective layer. At least one of the first electrode 105 and the second electrode 107 is preferably a transparent electrode as such a configuration increases the light extraction efficiency. Here, a refractive index of the transparent electrode is preferably lower than a refractive index of the light-emitting layer 106.

At least one of the first electrode 105 and the second electrode 107 is a transparent electrode having a refractive index lower than that of the light-emitting layer 106, and thus a portion of the light generated by the light-emitting layer 106 is totally reflected at an interface between the light-emitting layer 106 and the transparent electrode, propagates in the lateral direction, reaches the first light-exiting portion 104, and exits from the first opening 111.

The following describes, on the basis of (c) to (e) of FIG. 1, the movement of light generated by the light-emitting layer in a case in which the first electrode 105 and the second electrode 107 are transparent electrodes.

That is, as illustrated in (c) to (e) of FIG. 1, light generated by the light-emitting layer 106 and incident at an angle equal to or greater than a critical angle θ1 on an interface between the first electrode 105 and the second electrode 107 adjacent to each other is totally reflected at this interface, propagates in a lateral direction (direction parallel to the electrodes 105, 107), and reaches the first light-exiting portion 104 and the third light-reflecting layers 114a, 114b, 114c. The light reaching the first light-exiting portion 104 is reflected by an inclined face of the first light-reflecting layer 109, changes direction, and exits from the first opening 111 via the waveguide 110 (light X in FIG. 1(d)).

The light reaching the third light-reflecting layer 114a is reflected toward the first light-exiting portion 104, for example, and exits the first opening 111 as the light X. Further, the third light-reflecting layers 114b, 114c can each be formed with a vertical line of a surface relative to the light-emitting layer 106 being inclined toward the waveguide 110 side (FIG. 1(c)). In this case, for example, the light generated by the light-emitting layer 106 (dotted circle in FIG. 1(c)) is reflected by the third light-reflecting layer 114b, directed toward the first light-exiting portion 104, reflected by the first light-reflecting layer 109, and emitted externally as the light X (black spot in FIG. 1(c)). In this way, in a case in which the third light-reflecting layers 114b, 114c are formed with the vertical line of the surface relative to the light-emitting layer 106 being inclined toward the waveguide 110 side, the light reaching the third light-reflecting layers 114b, 114c is readily guided to the first opening 111 side and readily exits from the first opening 111 as the light X, and thus such a configuration is preferred.

Here, the critical angle θ1 changes in accordance with the difference in refractive index between the light-emitting layer 106 and the first electrode 105 as well as the second electrode 107.

The total reflection occurring at the interface between the light-emitting layer 106 and the transparent electrodes has superior reflection efficiency compared to metal reflection, allowing light to be propagated substantially without attenuation, and thus making it possible to increase the light extraction efficiency.

The first electrode 105 serving as the lower layer electrode, and the second electrode 107 serving as the upper layer electrode, serve as a pair of electrodes, with one functioning as an anode electrode and the other functioning as a cathode electrode. The first electrode 105 may be the cathode electrode, and the second electrode 107 may be the anode electrode. Conversely, the first electrode 105 may be the anode electrode, and the second electrode 107 may be the cathode electrode. In a case in which the anode electrode and cathode electrode are reversed, the layering order or carrier mobility (carrier transport properties, that is, hole transport properties and electron transport properties) of each function layer described below are reversed accordingly.

In a case in which the light-emitting element 102 is an OLED, positive holes and electrons recombine inside the light-emitting layer 106 in response to a drive current between the anode electrode and the cathode electrode, and light is emitted when the excitons generated in this manner transition to a ground state.

In a case in which the light-emitting element 102 is a QLED, positive holes and electrons recombine inside the light-emitting layer 106 in response to a drive current between the anode electrode and the cathode electrode, and light (fluorescence) is emitted when the excitons generated in this manner transition from the conduction band of the quantum dot to the valence band.

Electrode materials are not particularly limited, and known electrode materials may be employed.

Examples of the transparent electrode material include indium tin oxide (ITO), tin oxide (SnO2), indium zinc oxide (IZO), and gallium-added zinc oxide (GZO).

Examples of the reflective electrode material include a black electrode material such as tantalum (Ta) or carbon (C), Al, Ag, gold (Au), Al—Li alloy, Al-neodymium (Nd) alloy, and Al-silicon (Si) alloy.

Note that thicknesses of the first electrode 105 and the second electrode 107 are not limited to specific thicknesses, and may be set similarly to those in the prior art.

### Light-Emitting Layer 106

The light-emitting layer 106 is a layer having a function of emitting light by causing the holes (positive holes) injected from the anode electrode side and the electrons injected from the cathode electrode side to recombine so as to emit light, and utilizes quantum dots, for example, for light emission.

Various known types of light-emitting material may be employed as the material of the light-emitting layer (namely, a light-emitting substance), and the material is not limited to a specific material. A light-emitting material having a high light-emitting efficiency is preferably employed therefor, such as a low molecular weight fluorescent colorant or a metal complex.

Examples of the light-emitting material include anthracene, naphthalene, indene, phenanthrene, pyrene, naphthacene, triphenylene, perylene, picene, fluoranthene, acephenanthrylene, pentaphene, pentacene, coronene, butadiene, coumarin, acridine, stilbene, and derivatives thereof; a tris(8-quinolinolato)aluminum complex; a bis(benzoquinolinolato) beryllium complex; a tri(dibenzoylmethyl)phenanthroline europium complex; ditoluylvinylbiphenyl; and nanocrystals containing phosphors such as InP and CdSe.

A layer thickness of the light-emitting layer 106 is set as appropriate according to the light-emitting material, is not limited to a specific value, and is, for example, from about several nm to about several hundred nm.

Further, the light-emitting layer 106 may have a single layer configuration or may have a multilayer configuration including a plurality of layers.

### Function Layer

The light-emitting portion 102 may include further function layers between the first electrode 105 and the light-emitting layer 106 and between the light-emitting layer 106 and the second electrode 107, as necessary.

Typical examples of such a function layer include layers such as a hole injection layer, a hole transport layer, an electron transport layer, and an electron injection layer.

The hole injection layer is a layer including a hole injection material and having the function of increasing the hole injection efficiency from the anode electrode to the light-emitting layer 106. Further, the hole transport layer is a layer including a hole injection material and having the function of increasing the hole transport efficiency to the light-emitting layer 106. The electron injection layer is a layer including an electron injection and having the function of increasing the electron injection efficiency from the cathode electrode to the light-emitting layer 106. The electron transport layer is a layer including an electron transport material and having the function of increasing the electron transport efficiency to the light-emitting layer 106.

The hole injection layer and the hole transport layer may be formed as mutually independent layers, or may be integrated together as a hole injection-cum-transport layer. Similarly, the electron injection layer and the electron transport layer may be formed as mutually independent layers, or may be integrated together as an electron injection-cum-transport layer.

Only one of the hole injection layer and the hole transport layer may be provided. Similarly, only one of the electron injection layer and the electron transport layer may be provided.

Further, other than the function layer stated above, a carrier block layer, an intermediate layer, or the like may be provided.

Note that the material of these function layers and the like is also not limited, and known conventional materials may be employed as each such layers. Further, these function layers and the like are not essential layers, and layer thicknesses thereof are not limited to specific values. Thus, the description thereof is omitted in the present embodiment.

### Light Absorption Layer 108 and First Opening 111

The light absorption layer 108 is a layer for absorbing external light incident from the transparent substrate 112 side, which is an upper layer, and suppressing external light reflection.

Examples of the resin forming the light absorption layer 108 include a pigment-containing resin such as carbon black generally used for a black matrix.

The light absorption layer 108 is formed so as to include the first opening 111 on the second electrode 107. Here, a portion where the first opening 111 is provided corresponds to the first light-exiting portion 104, and the other portion corresponds to the light-emitting portion 103.

The first opening 111 may overlap or may not overlap the light-emitting layer 106, which is a lower layer underlying the light absorption layer 108, and the first electrode 105 and the second electrode 107, in a plan view. More preferably, the first opening 111 is provided so as not to overlap the light-emitting layer 106, the first electrode 105, and the second electrode 107, in a plan view. According to this configuration, the light reflected by the first light-reflecting layer 109 can be extracted to the outside from the first opening 111 without passing through the light-emitting layer 106, the first electrode 105, and the second electrode 107, which have different refractive indices from each other, thereby making the extraction efficiency even higher.

An area of the first opening 111 can be set as appropriate in accordance with the desired light extraction efficiency and suppression effect of the external light reflection.

By adjusting the inclination angle θ of the first light-reflecting layer 109 and an area ratio between the first opening 111 and the light-emitting portion 103 in accordance with the size of the subpixel and the thickness of the light-emitting element 102, it is possible to suppress the external light reflection without providing an anti-reflective film while ensuring favorable light extraction efficiency.

### First Light-Reflecting Layer 109

The first light-reflecting layer 109 is a layer provided at an incline on the substrate 101 at the inclination angle θ in the region of the first light-exiting portion 104.

The inclination angle θ can be set as appropriate so as to guide the light propagating from the light-emitting portion 103 to the first opening 111, and guide the external light incident from the first opening 111 to the light-emitting portion 103. By setting the inclination angle θ to 45° or less, preferably from 30° to 45°, for example, it is possible to extract the light generated by the light-emitting portion 103 more efficiently. On the other hand, by setting the inclination angle θ to greater than 45°, for example, it is possible to reduce the area of the first opening 111, and thus more reliably suppress the external light reflection. Note that the upper limit of the inclination angle is not particularly limited, but can be exemplified as less than 90°, for example.

Further, the inclined face of the first light-reflecting layer 109 may be constituted by one flat face or a combination of a plurality of flat faces, or may be constituted by one curved face or a combination of a plurality of curved faces, or may be constituted by a combination of one or a plurality of flat faces and one or a plurality of curved faces.

Note that the inclination angle θ refers to the angle at which a line segment connecting both end portions of the inclined face of the first light-reflecting layer 109 intersects the substrate 101 in a side view.

The first light-reflecting layer 109 can be formed of a material having high reflectivity such as, for example, a metal such as silver or aluminum.

### Second Embodiment

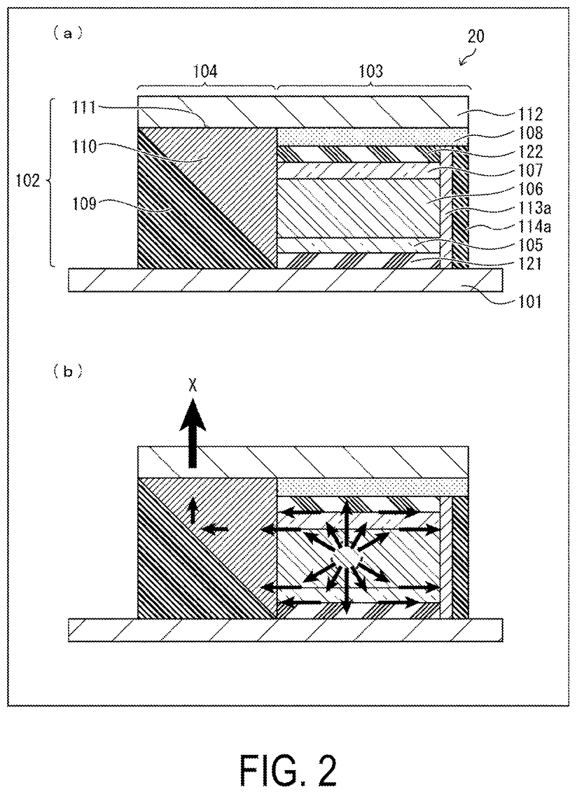

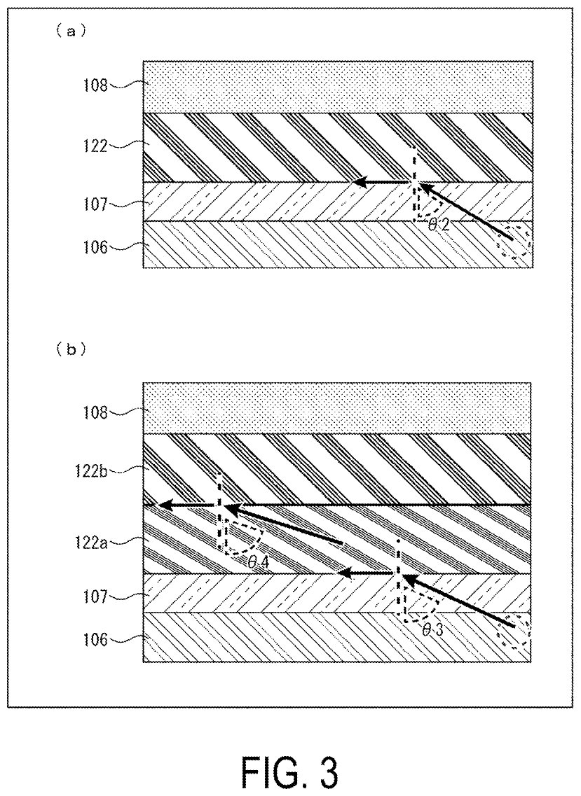

A second embodiment of the present invention will now be described with reference to FIG. 2 and FIG. 3.

(a) of FIG. 2 is a cross-sectional view schematically illustrating an example of a configuration of a display device according to the present embodiment (second embodiment), and (b) of FIG. 2 is a cross-sectional view describing movement of light generated in the light-emitting layer.

FIG. 3 describes the movement of light in the light-emitting portion of the display device according to the present embodiment, (a) being an enlarged cross-sectional view of a case in which a second light-reflecting layer is a single layer, and (b) being an enlarged cross-sectional view in a case in which the second light-reflecting layer is multi-layered. In (a) and (b) of FIG. 3, a configuration of lower layers below the light-emitting layer is omitted.

As illustrated in (a) of FIG. 2, a display device 20 according to the present embodiment differs from the display device of the first embodiment in further including second light-reflecting layers 121, 122 that reflect a portion of light generated by the light-emitting layer 106. Other matters are as described in the first embodiment.

Note that (a) of FIG. 2 illustrates a preferred embodiment, the second light-reflecting layer 121 is positioned between the substrate 101 and the first electrode 105, and the second light-reflecting layer 122 is positioned between the second electrode 107 and the light absorption layer 108. However, a quantity and a position of the second light-reflecting layer are not limited thereto. That is, the second light-reflecting layer may be configured to be positioned at least one of between the substrate 101 and the first electrode 105, between the first electrode 105 and the light-emitting layer 106, between the light-emitting layer 106 and the second electrode 107, and between the second electrode 107 and the light absorption layer 108. Further, the second light-reflecting layer may have a single layer configuration, or may have a multilayer configuration formed by layering a plurality of layers.

The second light-reflecting layer may be formed of any material capable of reflecting light at an interface with the adjacent layer. Examples of such materials include transparent resins such as polymethyl methacrylate having various refractive indices. The second light-reflecting layer may be a metal layer formed of a metal material such as silver or aluminum. The second light-reflecting layer may be a gas layer formed by a gas such as the atmosphere.

For example, the second light-reflecting layer may be a layer formed of a transparent resin, a metal layer, a gas layer, or a combination of these.

However, in a case in which the second light-reflecting layer is between the first electrode 105 and the light-emitting layer 106 and/or between the light-emitting layer 106 and the second electrode 107, the second light-reflecting layer is formed of a material having electrical conductivity.

In a preferred aspect of the present invention, the second light-reflecting layer may have a multilayer configuration including a layer made of a transparent resin positioned on the light-emitting layer 106 side and a metal layer positioned on the side opposite to the light-emitting layer 106.

In one aspect of the present invention, the at least one second light-reflecting layer is preferably a layer formed of a transparent resin as such a configuration increases the light extraction efficiency. Here, a refractive index of the second light-reflecting layer is preferably lower than the refractive index of the light-emitting layer 106.

The following describes, on the basis of (b) of FIG. 2 and (a) of FIG. 3, the movement of light generated by the light-emitting layer 106 in a case in which the first electrode 105 and the second electrode 107 are transparent electrodes and the second light-reflecting layers 121, 122 are layers formed of a transparent resin.

As illustrated in (b) of FIG. 2, in the display device 20 according to the present embodiment, the light generated by the light-emitting layer 106 is totally reflected at the interface in accordance with the refractive index differences between the layers, propagates in the lateral direction, and reaches the first light-exiting portion 104. The light reaching the first light-exiting portion 104 is reflected by the inclined face of the first light-reflecting layer 109, and exits from the first opening 111 via the waveguide 110 (light X of FIG. 2).

Here, to achieve total reflection, the first electrode 105, the second electrode 107, and the second light-reflecting layers 121, 122 are preferably layered so that the refractive index decreases from the layer closest to the light-emitting layer 106 toward the layer farthest from the light-emitting layer 106.

For example, the refractive index of the second light-reflecting layer 121 positioned between the first electrode 105 and the substrate 101 is preferably lower than the refractive index of the first electrode 105. Similarly, the refractive index of the second light-reflecting layer 122 positioned between the second electrode 107 and the light absorption layer 108 is preferably lower than the refractive index of the second electrode 107.

With such a configuration, as illustrated in (a) of FIG. 3, of the light generated by the light-emitting layer 106, light incident on the interface between the second electrode 107 and the second light-reflecting layer 122 at an angle equal to or greater than a critical angle θ2 is totally reflected at this interface and propagates in the lateral direction.

More specifically, in a preferred aspect of the present embodiment, the refractive index of the light-emitting layer is 2, the second electrode 107 is composed of indium tin oxide having a refractive index of 2, and the second light-reflecting layer 122 is formed of polymethyl methacrylate having a refractive index of 1.5. At this time, the critical angle θ2 is 49°.

Accordingly, of the light generated by the light-emitting layer 106, light incident on the interface between the second electrode 107 and the second light-reflecting layer 122 at an angle equal to or greater than 49° (approximately 46%) is totally reflected at this interface between layers and propagates in the lateral direction. On the other hand, light incident at an angle of less than 49° travels in the second light-reflecting layer 122, reaches the light absorption layer 108, and is absorbed. In this aspect, approximately 46% of the light generated by the light-emitting layer 106 can be extracted from the first opening 111 by total reflection.

Next, on the basis of (b) of FIG. 3, the movement of light generated by the light-emitting layer in a case in which the second light-reflecting layer includes a plurality of layers formed of a transparent resin will be described below.

In a case in which the second light-reflecting layer has a multilayer configuration formed by layering a plurality of layers, the plurality of layers are layered so that the refractive index decreases from the layer closest to the light-emitting layer 106 toward the layer farthest from the light-emitting layer 106, and the refractive index of the layer closest to the light-emitting layer 106 is preferably lower than that of the light-emitting layer 106.

For example, as illustrated in (b) of FIG. 3, in a case in which second light-reflecting layers 122a, 122b of a two-layer configuration are positioned between the second electrode 107 and the light absorption layer 108, a refractive index of the second light-reflecting layer 122b is lower than a refractive index of the second light-reflecting layer 122a, and the refractive index of the second light-reflecting layer 122a is preferably lower than the refractive index of the second electrode 107.

With such a configuration, of the light generated by the light-emitting layer 106, light incident on an interface between the second electrode 107 and the second light-reflecting layer 122a at an angle equal to or greater than a critical angle θ3 is totally reflected at this interface and propagates in the lateral direction. Further, at an interface between the second light-reflecting layer 122a and the second light-reflecting layer 122b, light incident at an angle equal to or greater than a critical angle θ4 is totally reflected at this interface and propagates in the lateral direction.

More specifically, in a preferred aspect of the present embodiment, the refractive index of the light-emitting layer 106 is 2, the second electrode 107 is composed of indium tin oxide having a refractive index of 2, the second light-reflecting layer 122a is formed of polymethyl methacrylate having a refractive index of 1.7, and the second light-reflecting layer 122b is formed of a polymethyl methacrylate having a refractive index of 1.5. At this time, the critical angle θ3 is 58°, and the critical angle θ4 is 62°.

Accordingly, of the light generated by the light-emitting layer 106, light incident on the interface between the second electrode 107 and the second light-reflecting layer 122a at an angle equal to or greater than 58° (approximately 35%) is totally reflected at the interface between the layers and propagates in the lateral direction. On the other hand, light incident at an angle of less than 58° travels in the second light-reflecting layer 122a and reaches the interface with the second light-reflecting layer 122b. Here, the light incident on the interface at an angle of 62° or greater (approximately 20%) is totally reflected at the interface between the layers and propagates in the lateral direction. In this aspect, approximately 55% of the light generated by the light-emitting layer 106 can be extracted from the opening 111 by total reflection.

By increasing the number of layers of the second light-reflecting layer, it is possible to further enhance the light extraction efficiency.

### Third Embodiment

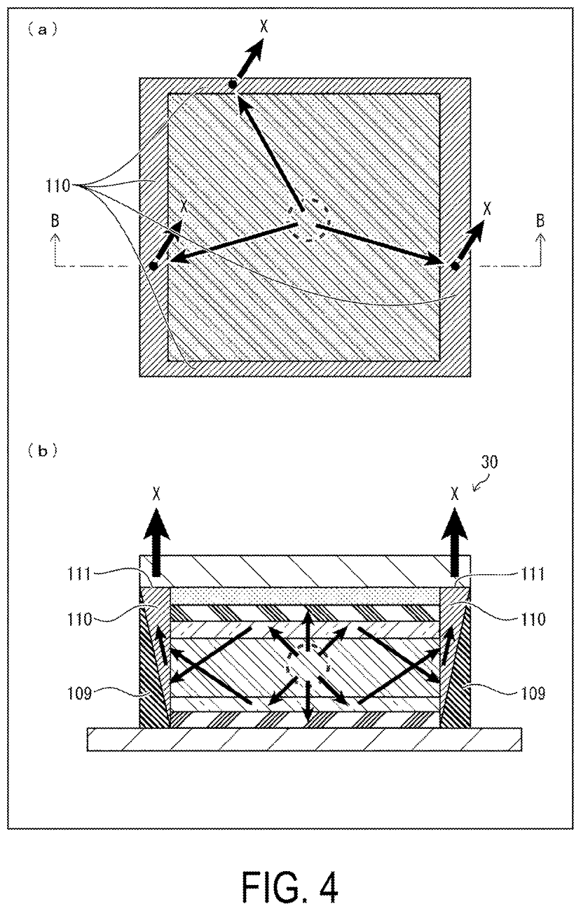

A third embodiment of the present invention will now be described with reference to (a) and (b) of FIG. 4.

FIG. 4 schematically illustrates an example of a configuration of a display device according to the present embodiment (third embodiment), (a) being a plan view as viewed from a viewing side, and (b) being a cross-sectional view taken along line B-B in (a).

As illustrated in (a) and (b) of FIG. 4, a display device 30 according to the present embodiment differs from the display device in the second embodiment in that the first light-exiting portion 104 (first light-reflecting layer 109, waveguide 110, and first opening 111) is formed surrounding the light-emitting layer 106. Other matters are as described in the first and second embodiments.

In (a) and (b) of FIG. 4, the first light-exiting portion 104 is provided adjacent to all four sides of the light-emitting layer 106 having a quadrangular shape, but may be provided adjacent to either two or three of the four sides.

By providing the first light-exiting portion 104 adjacent to two or more of the four sides of the light-emitting layer 106, it is possible to shorten a waveguide distance of the light generated by the light-emitting layer 106. As a result, it is possible to reduce loss due to attenuation and other factors during propagation.

### Fourth Embodiment

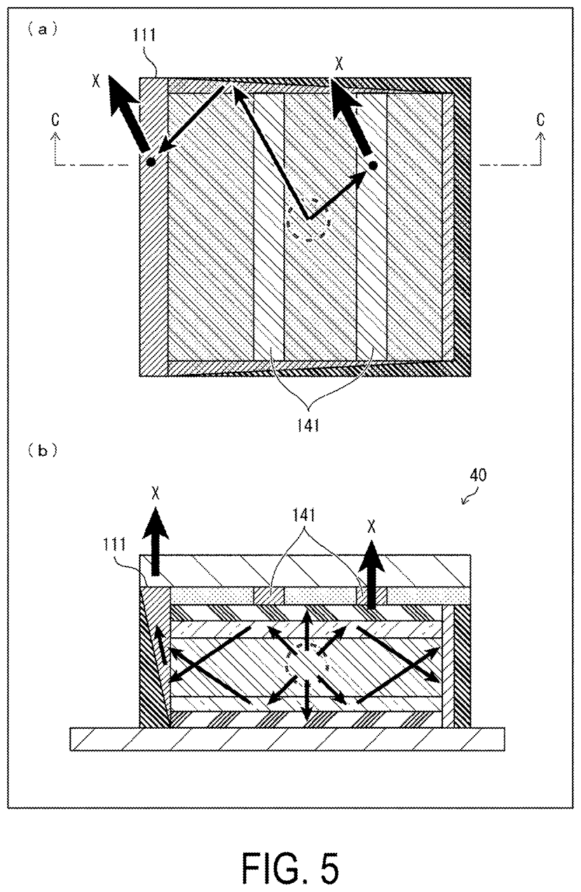

A fourth embodiment of the present invention will now be described with reference to (a) and (b) of FIG. 5.

FIG. 5 schematically illustrates an example of a configuration of a display device according to the present embodiment (fourth embodiment), (a) being a plan view as viewed from a viewing side, and (b) being a cross-sectional view taken along line C-C in (a).

As illustrated in (a) and (b) of FIG. 5, a display device 40 according to the present embodiment differs from the display device in the second embodiment in including a second light-exiting portion including a second opening 141 provided in the light absorption layer 108, the second opening 141 overlapping the light-emitting layer 106. Other matters are as described in the first and second embodiments.

In (a) and (b) of FIG. 5, the second opening 141 is constituted by two slits provided parallel to the first opening 111. The number and shape of the second opening 141, however, are not limited thereto, and the second opening of any number and shape can be provided to the extent that the effect of the present invention is not impaired.

While an anti-reflective film such as an existing circularly-polarized light filter reduces the external light reflection by about 95%, there is a problem in that the transmission of light from the light-emitting layer to the outside is reduced by about 50%. In contrast, in the display device according to the present embodiment, by adjusting an opening area of the second opening 141, it is possible to achieve a desired reduction rate of external light reflection without inhibiting the transmission of light from the light-emitting layer. For example, by setting the opening area of the second opening 141 to 10% or less, more preferably 5% or less, of the area of the light-emitting layer 106, it is possible to reduce the external light reflection at a level equivalent to an existing anti-reflective film without causing light transmission loss. Note that a lower limit value of the opening area of the second opening 141 is not particularly limited, and need only be greater than 0% of the area of the light-emitting layer 106.

Of the light generated in the light-emitting layer 106, light not totally reflected at interfaces such as those with the first electrode 105 and the second electrode 107 may reach and be absorbed by the light absorption layer 108, for example, and may not reach the first light-exiting portion 104.

With the second opening 141 overlapping the light-emitting layer 106, of the light generated by the light-emitting layer 106, the light that does not reach the first light-exiting portion 104 can also be partially extracted via the second opening 141.

### Fifth Embodiment

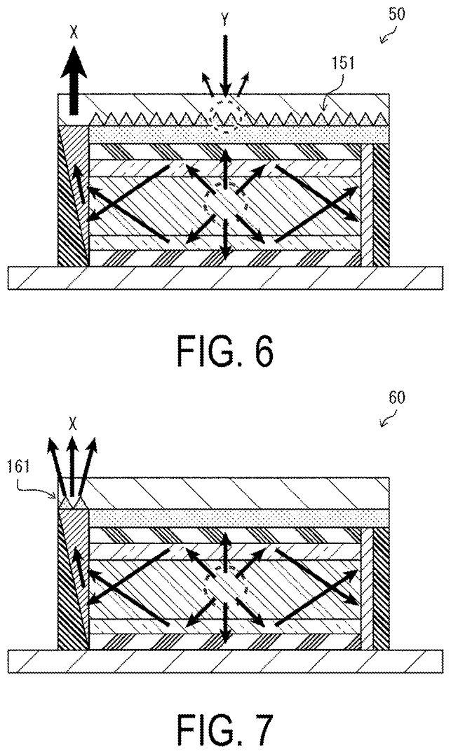

A fifth embodiment of the present invention will now be described with reference to FIG. 6.

FIG. 6 is a cross-sectional view schematically illustrating an example of a configuration of a display device according to the present embodiment (fifth embodiment).

As illustrated in FIG. 6, a display device 50 according to the present embodiment differs from the display device in the second embodiment in that an unevenness 151 is formed on a surface of the light absorption layer 108 on a side opposite to the light-emitting layer 106. Other matters are as described in the first and second embodiments.

Such unevenness 151 can be formed by, for example, shaving a surface of the light absorption layer 108.

By providing the unevenness 151, it is possible to scatter external light Y incident from the transparent substrate 112 side by recessed portions or protruding portions of the unevenness 151, and more reliably prevent external light reflection.

### Sixth Embodiment

A sixth embodiment of the present invention will now be described with reference to FIG. 7.

FIG. 7 is a cross-sectional view schematically illustrating an example of a configuration of a display device according to the present embodiment (sixth embodiment).

As illustrated in FIG. 7, a display device 60 according to the present embodiment differs from the display device in the second embodiment in that an unevenness 161 is formed on a surface of the waveguide 110 on the first opening 111 side. Other matters are as described in the first and second embodiments.

Such an unevenness 161 can be formed by, for example, shaving a surface of the waveguide 110.

By providing the unevenness 161, it is possible to scatter the light X exiting from the first opening 111 by recessed portions or protruding portions to widen the viewing angle.

### Seventh Embodiment

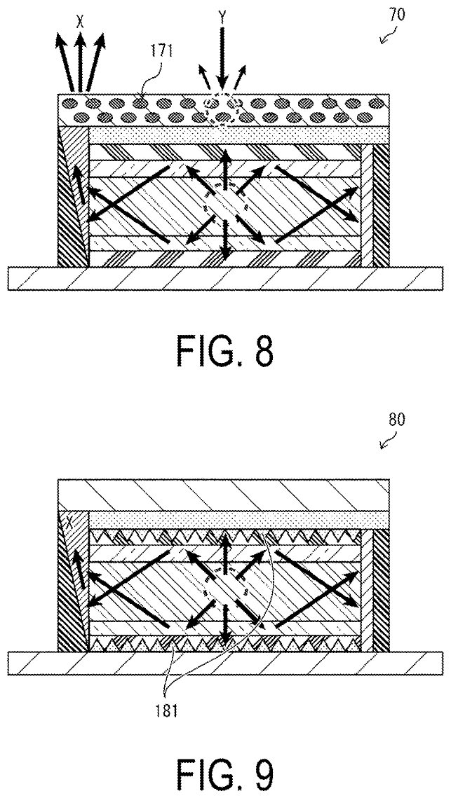

A seventh embodiment of the present invention will now be described with reference to FIG. 8.

FIG. 8 is a cross-sectional view schematically illustrating an example of a configuration of a display device according to the present embodiment (seventh embodiment).

As illustrated in FIG. 8, a display device 70 according to the present embodiment differs from the display device in the second embodiment in that a light-scattering layer 171 that scatters light is provided on a side of the light absorption layer 108 opposite to the light-emitting layer 106. Other matters are as described in the first and second embodiments.

The light-scattering layer 171 can be formed by, for example, mixing, in the transparent resin for forming the transparent substrate 112, a light-scattering substance such as fine particles having a refractive index different from that of the resin.

By providing the light-scattering layer 171, it is possible to scatter the external light Y and thus more reliably prevent external light reflection, and scatter the light X exiting from the first opening 111 and thus widen the viewing angle.

### Eighth Embodiment

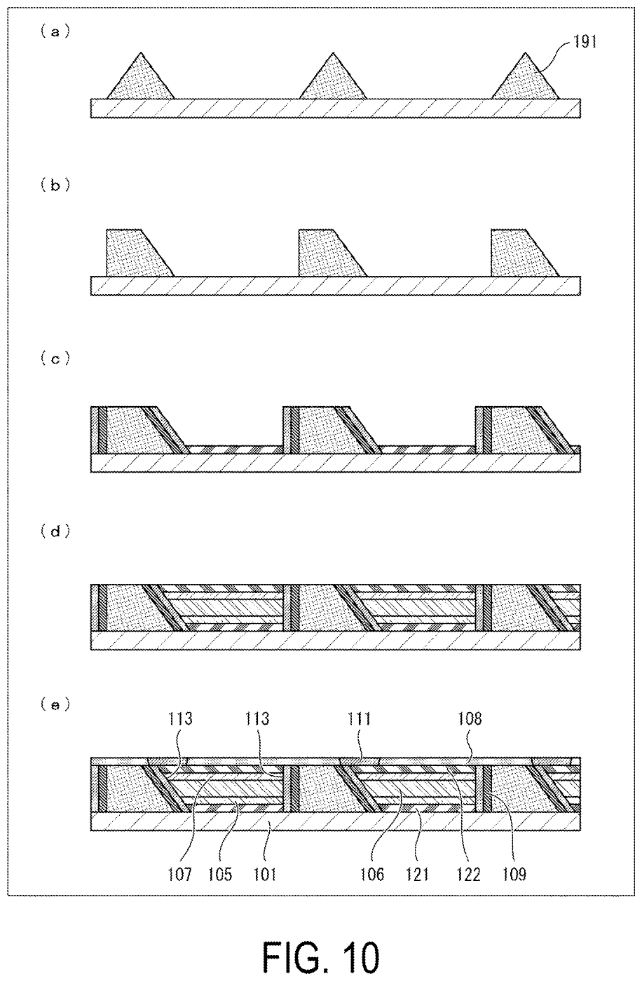

An eighth embodiment of the present invention will now be described with reference to FIG. 9.

FIG. 9 is a cross-sectional view schematically illustrating an example of a configuration of a display device according to the present embodiment (eighth embodiment).

As illustrated in FIG. 9, a display device 80 according to the present embodiment differs from the display device in the second embodiment in including another second light-reflecting layer 181 between the substrate 101 and the second light-reflecting layer 121, and between the second light-reflecting layer 122 and the light absorption layer 108. Other matters are as described in the first and second embodiments.

Here, on the other second light-reflecting layer 181, unevenness is formed on a surface facing the light-emitting layer 106.

The second light-reflecting layer 181 having such unevenness can be formed by, for example, providing a concave-convex structure on the underlayer by using a nanoprint technique and then vapor-depositing a reflective film of a metal thereon.

When, of the light generated by the light-emitting layer 106, light incident at an angle less than the critical angle and thus not totally reflected reaches an interface with the second light-reflecting layer 181, the light collides with the unevenness of this second light-reflecting layer 181, changes in angle, and is returned to the light-emitting layer 106. The returned light is then incident on the interface on the opposite side at an angle greater than or equal to the critical angle and is totally reflected.

Accordingly, by providing the second light-reflecting layer 181 with such unevenness formed thereon, it is possible to further enhance the light extraction efficiency.

### Ninth Embodiment

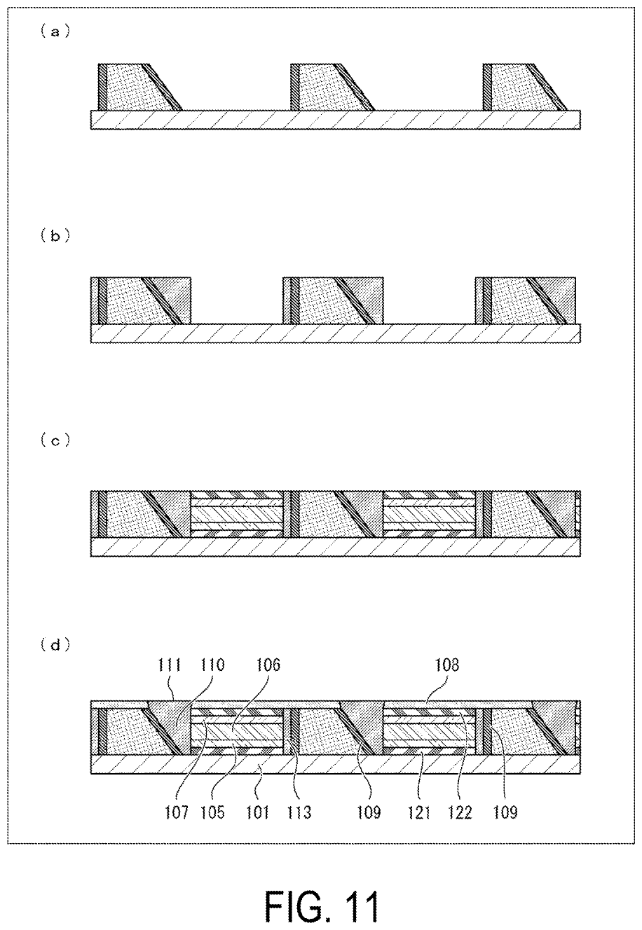

A ninth embodiment of the present invention will now be described with reference to FIG. 10.

FIG. 10 is a diagram illustrating a manufacturing method of a display device according to the present embodiment (ninth embodiment).

First, as illustrated in (a) of FIG. 10, a base 191 having a forwardly tapered shape and composed of an insulating material is created on a substrate. Here, a gradient of the forward taper can be suitably set in accordance with the inclination angle θ of the first light-reflecting layer 109.

Next, as illustrated in (b) of FIG. 10, insulating material is added so as to fill the tapered portion on one side of the base 191 creating a base having a substantially trapezoidal cross-sectional shape with a vertical face and an inclined face.

Next, as illustrated in (c) of FIG. 10, the first light-reflecting layer 109 made of metal material is formed covering the vertical face and the inclined face of the base, and the insulating transparent layer 113 formed of an insulating transparent resin is formed on this first light-reflecting layer 109. Next, the second light-reflecting layer 121 is formed on the substrate 101.

Next, as illustrated in (d) of FIG. 10, the first electrode 105, the light-emitting layer 106, the second electrode 107, and the second light-reflecting layer 122 are layered in this order on the second light-reflecting layer 121.

Next, as illustrated in (e) of FIG. 10, the light absorption layer 108 is layered on the second light-reflecting layer 122, and the first opening 111 is provided in a region overlapping the inclined face of the base portion 191 in a plan view.

By the process described above, the display device according to the present embodiment is obtained.

### Tenth Embodiment

A tenth embodiment of the present invention will now be described with reference to FIG. 11.

FIG. 11 is a diagram illustrating a manufacturing method of a display device according to the present embodiment (tenth embodiment).

First, as illustrated in (a) of FIG. 11, in the same manner as in the ninth embodiment, a base having a substantially trapezoidal cross-sectional shape with a vertical face and an inclined face is created on the substrate 101, and the first light-reflecting layer 109 made of a metal material is formed covering the vertical face and inclined face.

Next, as illustrated in (b) of FIG. 11, areas between the bases are filled with insulating transparent resin and the insulating transparent resin is subsequently partially removed, forming the waveguide 110 with the tapered portion of the inclined face of the base being filled, and the insulating transparent layer 113 covering the vertical face of the base.

Next, as illustrated in (c) of FIG. 11, the second light-reflecting layer 121, the first electrode 105, the light-emitting layer 106, the second electrode 107, and the second light-reflecting layer 122 are layered in this order on the substrate 101.

Next, as illustrated in (d) of FIG. 10, the light absorption layer 108 is layered on the second light-reflecting layer 122, and the first opening 111 is provided in a region overlapping the waveguide 110 in a plan view.

By the process described above, the display device according to the present embodiment is obtained.

### Eleventh Embodiment

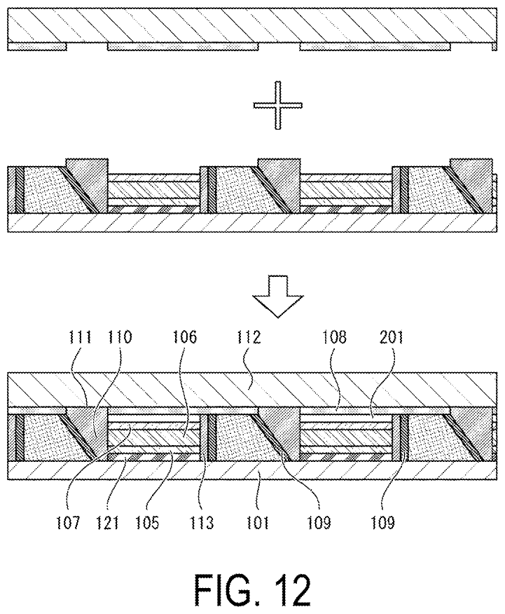

An eleventh embodiment of the present invention will now be described with reference to FIG. 12.

FIG. 12 is a diagram illustrating a manufacturing method of a display device according to the present embodiment (eleventh embodiment).

First, in the same manner as in the tenth embodiment, a layered body is prepared by layering, on the substrate 101, the base, the first light-reflecting layer 109, the waveguide 110, the insulating transparent layer 113, the second light-reflecting layer 121, the first electrode 105, the light-emitting layer 106, and the second electrode 107. Here, unlike the tenth embodiment, the second light-reflecting layer 121 made of resin is not layered on the second electrode 107.

On the other hand, the light absorption layer 108 is layered on and the first opening 111 is provided in one surface of the transparent substrate 112 serving as the protection layer.

Next, the layered body obtained above and the transparent substrate 112 in which the light absorption layer 108 is layered are aligned so that the waveguide 110 and the first opening 111 overlap.

As a result, a gas layer 201 that encloses air is formed between the second electrode 107 and the light absorption layer 108.

By the process described above, the display device according to the present embodiment is obtained.

### Supplement

### First Aspect

A display device includes a substrate and a light-emitting element provided on the substrate. The light-emitting element includes a light-emitting portion and a first light-exiting portion adjacent to the light-emitting portion. The light-emitting portion includes, in order from the substrate side, a first electrode, a light-emitting layer, a second electrode, and a light absorption layer. The first light-exiting portion includes a first light-reflecting layer provided at an incline on the substrate, and a first opening provided in the light absorption layer.

### Second Aspect

In the display device according to the first aspect, for example, at least one second light-reflecting layer is provided between the substrate and the first electrode, between the first electrode and the light-emitting layer, between the light-emitting layer and the second electrode, and between the second electrode and the light absorption layer, and a portion of light generated by the light-emitting layer is reflected by the at least one second light-reflecting layer and guided to the first light-exiting portion.

### Third Aspect

In the display device according to the second aspect, for example, the at least one second light-reflecting layer has a refractive index lower than that of the light-emitting layer.

### Fourth Aspect

In the display device according to the second aspect, for example, the second light-reflecting layer is constituted by a plurality of layers, the plurality of layers have a refractive index that decreases in order from a layer closest to the light-emitting layer to a layer farthest from the light-emitting layer, and the layer closest to the light-emitting layer has a refractive index lower than that of the light-emitting layer.

### Fifth Aspect

In the display device according to any one of the second to fourth aspects, for example, the at least one second light-reflecting layer includes a metal layer formed of a metal material.

### Sixth Aspect

In the display device according to any one of the second to fifth aspects, for example, the at least one second light-reflecting layer includes a gas layer formed of a gas.

### Seventh Aspect

In the display device according to any one of the second to sixth aspects, for example, the at least one second light-reflecting layer has unevenness on a surface opposing the light-emitting layer.

### Eighth Aspect

In the display device according to any one of the second to seventh aspects, for example, the light absorption layer has unevenness on a surface on a side opposite to the light-emitting layer.

### Ninth Aspect

In the display device according to any one of the second to eighth aspects, for example, the first opening has unevenness on an opening face.

### Tenth Aspect

The display device according to any one of the second to ninth aspects further includes, for example, a light-scattering layer provided on a surface of the light absorption layer on a side opposite to the light-emitting layer and configured to scatter light.

### Eleventh Aspect

In the display device according to any one of the first to tenth aspects, for example, side surfaces of the light-emitting layer include a contact surface in contact with the first light-exiting portion, an opposing side surface opposing the contact surface, and an intersecting side surface that intersects the contact surface. An insulating transparent layer and a third light-reflecting layer are provided in this order on the opposing side surface and the intersecting side surface, and a reflective surface of the third light-reflecting layer on the intersecting side surface intersects the first light-exiting portion at an intersection angle less than 90° in a plan view.

### Twelfth Aspect

In the display device according to any one of the first to tenth aspects, for example, the first light-exiting portion surrounds the light-emitting layer.

### Thirteenth Aspect

In the display device according to any one of the first to twelfth aspects, for example, the first opening does not overlap the light-emitting layer.

### Fourteenth Aspect

The display device according to any one of the first to thirteenth aspects further includes, for example, a second light-exiting portion including a second opening provided in the light absorption layer, the second opening overlapping the light-emitting layer.

### Additional Items

The present invention is not limited to the embodiments described above, and embodiments obtained by appropriately combining technical approaches disclosed in the different embodiments also fall within the technical scope of the present invention. Furthermore, novel technical features can be formed by combining the technical approaches disclosed in each of the embodiments.

The display device according to the present embodiment is not particularly limited as long as the display device is a display panel provided with display elements such as light-emitting elements. The display element is a display element in which luminance and transmittance are controlled by an electric current, and examples of the electric current-controlled display element include an organic electro-luminescence (EL) display provided with an organic light-emitting diode (OLED), an EL display such as an inorganic EL display provided with an inorganic light-emitting diode, and a quantum dot light-emitting diode (QLED) display provided with a QLED.

### REFERENCE SIGNS LIST

10, 20, 30, 40, 50, 60, 70, 80 Display device
101 Substrate
102 Light-emitting element
103 Light-emitting portion
104 First light-exiting portion
105 First electrode
106 Light-emitting layer
106a Opposing side surface
106b, 106d Intersecting side surface
106d Contact surface
107 Second electrode
108 Light absorption layer
109 First light-reflecting layer
110 Waveguide
111 First opening
112 Transparent substrate
113a, 113b, 113c Insulating transparent layer
114a, 114b, 114c Third light-reflecting layer
121, 122, 122a, 122b, 181 Second light-reflecting layer
141 Second opening
171 Light-scattering layer
201 Gas layer

1. A display device comprising:
a substrate; and
a light-emitting element provided on the substrate,
wherein the light-emitting element includes
a light-emitting portion, and
a first light-exiting portion adjacent to the light-emitting portion,
the light-emitting portion includes, in order from the substrate side,
a first electrode,
a light-emitting layer,
a second electrode, and
a light absorption layer, and
the first light-exiting portion includes
a first light-reflecting layer provided at an incline on the substrate, and
a first opening provided in the light absorption layer.

2. The display device according to claim 1,
wherein at least one second light-reflecting layer is provided between the substrate and the first electrode, between the first electrode and the light-emitting layer, between the light-emitting layer and the second electrode, and between the second electrode and the light absorption layer, and
a portion of light generated by the light-emitting layer is reflected by the at least one second light-reflecting layer and guided to the first light-exiting portion.

3. The display device according to claim 2,
wherein the at least one second light-reflecting layer has a refractive index lower than that of the light-emitting layer.

4. The display device according to claim 2,
wherein the at least one second light-reflecting layer is constituted by a plurality of layers,
the plurality of layers have a refractive index that decreases in order from a layer closest to the light-emitting layer to a layer farthest from the light-emitting layer, and
the layer closest to the light-emitting layer has a refractive index lower than that of the light-emitting layer.

5. The display device according to claim 2,
wherein the at least one second light-reflecting layer includes a metal layer formed of a metal material.

6. The display device according to claim 2,
wherein the at least one second light-reflecting layer includes a gas layer formed of a gas.

7. The display device according to claim 2,
wherein the at least one second light-reflecting layer has unevenness on a surface opposing the light-emitting layer.

8. The display device according to claim 2,
wherein the light absorption layer has unevenness on a surface on a side opposite to the light-emitting layer.

9. The display device according to claim 2,
wherein the first opening has unevenness on an opening face.

10. The display device according to claim 2, further comprising:
a light-scattering layer provided on a surface of the light absorption layer on a side opposite to the light-emitting layer and configured to scatter light.

11. The display device according to claim 1,
wherein side surfaces of the light-emitting layer include
a contact surface in contact with the first light-exiting portion,
an opposing side surface opposing the contact surface, and
an intersecting side surface that intersects the contact surface,
an insulating transparent layer and a third light-reflecting layer are provided in this order on the opposing side surface and the intersecting side surface, and
a reflective surface of the third light-reflecting layer on the intersecting side surface intersects the first light-exiting portion at an intersection angle less than 90° in a plan view.

12. The display device according to claim 1,
wherein the first light-exiting portion surrounds the light-emitting layer.

13. The display device according to claim 1,
wherein the first opening does not overlap the light-emitting layer.

14. The display device according to claim 1, further comprising:
a second light-exiting portion including a second opening provided in the light absorption layer, the second opening overlapping the light-emitting layer.
